(19) United States
(12) Patent Application Publication
(10) Pub. No.: US 2016/0283145 A1
(43) Pub. Date: Sep. 29, 2016

(54) Electronic Device, Power Failure Protection Method and Data Recovery Method

(71) Applicant: LENOVO (BEIJING) CO., LTD., Beijing (CN)

(72) Inventors: Xiaolei Han, Beijing (CN); Jun Liu, Beijing (CN); Jie Yang, Beijing (CN)

(73) Assignee: LENOVO (BEIJING) CO., LTD., Beijing (CN)

(21) Appl. No.: 14/827,452

(22) Filed: Aug. 17, 2015

(30) Foreign Application Priority Data
Mar. 24, 2015 (CN) 201510128984.6
Mar. 24, 2015 (CN) 201510129162.X

(51) Int. Cl. G06F 3/06; G06F 1/30; G11C 5/14

(52) U.S. Cl. CPC G06F 3/0619; G11C 5/141; G11C 5/148; G06F 3/0647; G06F 3/0685; G06F 1/30

(57) ABSTRACT

Provided are an electronic device, a power failure protection method, and a data recovery method. The electronic device includes a backup power supply unit, a volatile storage unit and a control unit. The power failure protection method includes starting the backup power supply unit to supply power to the volatile storage unit and the control unit temporarily when a power supply of the electronic device is shut down; connecting the volatile storage unit to an external device; and reading out the data stored in the volatile storage unit and providing the same to the external device.

This application claims priority to Chinese patent application No. 201510128984.6 filed on Mar. 24, 2015, and also to Chinese patent application No. 201510129162.X filed on Mar. 24, 2015; the entire contents of each are incorporated herein by reference.

The present disclosure relates to an electronic device, a power failure protection method, and a data recovery method.

### BACKGROUND

Since memory of an electronic device such as a desktop computer, a notebook computer and so on is a volatile storage medium, data in memory of a running electronic device will be lost as the data cannot be written into a hard disk timely when a power failure happens to the electronic device suddenly due to power-off or man-made mis-operation, which may cause heavy losses for a user. In order to overcome such problem, a commonly used measure is to connect two electronic devices together with an infiniband (IB) card to synchronize memories of the two electronic devices continuously, so as to protect data from being lost and thus achieve power failure protection. However, such solution with the IB card has disadvantages of high-cost and no guarantee of consistence between the memories of the two electronic devices at the moment when a power failure happens.

### SUMMARY

In order to solve the above technical problem, the present disclosure aims to propose an electronic device and a power failure protection method capable of avoiding loss of data in memory of the electronic device and a data recovery method capable of recovering the data in the memory of the electronic device in another electronic device in a case where a power failure happens to the electronic device suddenly.

According to one aspect of the present disclosure, there is provided an electronic device comprising: a backup power supply unit configured to supply power to a volatile storage unit and a control unit temporarily when a power supply of the electronic device is shut down; the volatile storage unit configured to store data when being supplied power; the control unit configured to provide the data stored in the volatile storage unit to an external device when the power supply of the electronic device is shut down or the control unit is supplied power by the backup power supply unit; and a communication module configured to connect the volatile storage unit to the external device so as to provide the data stored in the volatile storage unit to the external device.

According to another aspect of the present disclosure, there is provided a power failure protection method applied to an electronic device comprising a backup power supply unit, a volatile storage unit and a control unit, the power failure protection method comprises: starting the backup power supply unit to supply power to the volatile storage unit and the control unit temporarily when a power supply of the electronic device is shut down; connecting the volatile storage unit to an external device; and reading out the data stored in the volatile storage unit and providing the same to the external device.

According to yet another aspect of the present disclosure, there is provided a data recovery method comprising: acquiring, by a communication module of a first electronic device, virtual machine data and indication information of the virtual machine data from a second electronic device, the virtual machine data being data used by at least one virtual machine running on the second electronic device, and the indication information of the virtual machine data indicating a corresponding relationship between the virtual machine data and the virtual machine and indicating order of storage of the virtual machine data; acquiring data belonging to a same virtual machine from the virtual machine data according to the indication information of the virtual machine data; determining order of storage of the data belonging to the same virtual machine according to the indication information of the virtual machine data; combining the data belonging to the same virtual machine according to the order of storage of the data belonging to the same virtual machine, so as to recover data having an order of storage same as that of the data belonging to the same virtual machine in the second electronic device.

### BRIEF DESCRIPTION OF THE DRAWINGS

The above and other objects, advantages and features of the present disclosure will be understood better and more completely with reference to accompanying drawings, in which:

FIG. 1 is diagram illustrating configuration of an electronic device according to a first embodiment of the present disclosure;

FIG. 2 is diagram illustrating configuration of an electronic device according to a second embodiment of the present disclosure;

FIG. 3 is a flowchart illustrating a power failure protection method applied to an electronic device according to the embodiments of the present disclosure;

FIG. 4 is a flowchart illustrating a data recovery method provided in the embodiments of the present disclosure;

FIG. 5 is a schematic diagram illustrating information acquisition in the data recovery method provided in the embodiments of the present disclosure;

FIG. 6 is a flowchart illustrating step S402 in the data recovery data provided in the embodiments of the present disclosure;

FIG. 7 is a flowchart illustrating step S403 in the data recovery method provided in the embodiments of the present disclosure;

FIG. 8 is a schematic diagram illustrating structure of a data recovery apparatus provided in the embodiments of the present disclosure;

FIG. 9 is a schematic diagram illustrating structure of a second acquiring unit in the data recovery apparatus provided in the embodiments of the present disclosure; and

FIG. 10 is a schematic diagram illustrating structure of a determining unit in the data recovery apparatus provided in the embodiments of the present disclosure.

### DETAILED DESCRIPTION

Hereinafter, preferable embodiments of the present disclosure will be described with reference to the accompanying drawings. In the description and the accompanying drawings of the present disclosure, same or similar reference signs will be adopted to represent essentially same elements and functions, and repeated explanations for these elements and functions will be omitted. In addition, for sake of clear and concise, explanations for well-known functions and structures will be omitted.

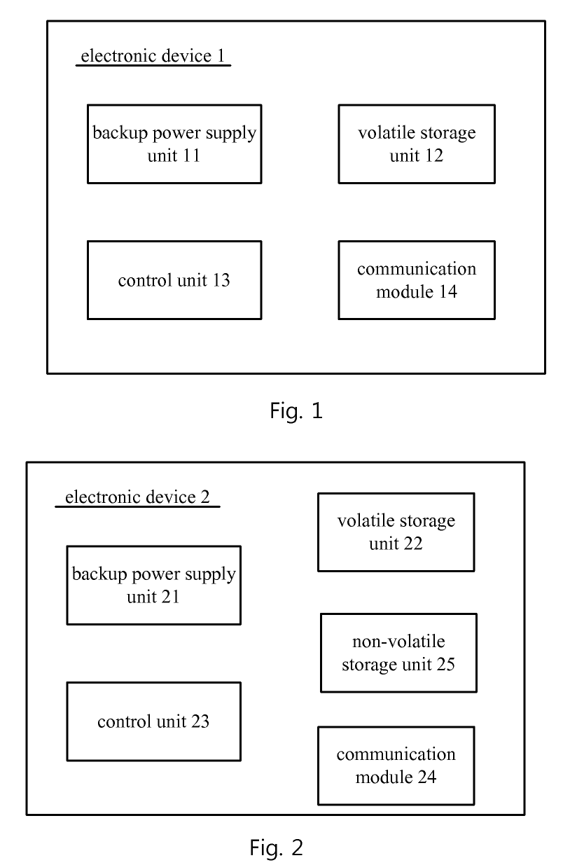

FIG. 1 is diagram illustrating configuration of an electronic device 1 according to a first embodiment of the present disclosure. The electronic device 1 may be an electronic device such as a desktop computer, a notebook computer, a tablet computer, a smart phone, a personal digital assistance, a wearable device, and so on.

As shown in FIG. 1, the electronic device 1 comprises a backup power supply unit 11, a volatile storage unit 12, a control unit 13 and a communication module 14.

The backup power supply unit 11 is configured to supply power to the volatile storage unit 12 and the control unit 13 temporarily when a power supply of the electronic device 1 is shut down. In the first embodiment of the present disclosure, preferably the backup power supply unit 11 is a super capacitor, for example, an electrical double-layer super capacitor and a pseudo-capacitor super capacitor, however the present disclosure is not so limited. The backup power supply unit 11 may further be a power supply capable of supplying power to components of the electronic device, such as a Lithium battery pack, a storage battery pack and so on.

When the power supply of the electronic device is shut down, a time period during which the backup power supply unit 11 supplies power is not a fixed time period, but is determined by a time period during which the electronic device actually performs power failure protection operation (described in detail hereinafter). Parameters having an effect on the time period during which the electronic device actually performs power failure protection operation comprise amount of data stored in the volatile storage unit 12, processing speed of the control unit 13, data receiving speed of an external device, and so on. In the first embodiment of the present disclosure, the backup power supply unit 11 supplies power only during the power failure protection operation of the electronic device 1, and stops supplying power when the electronic device 1 performs the power failure protection operation completely, that is, the external device has received all of data stored in the volatile storage unit 12. However, the time period during which the backup power supply unit 11 supplies power has a limit since amount of electricity of the backup power supply unit 11 such as a super capacitor is limited. Type and capacity of the backup power supply unit 11 can be selected appropriately by those skilled in the art in consideration of the above respective parameters comprehensively.

The volatile storage unit 12 is configured to store data when being supplied power. The volatile storage unit 12 is for example a memory.

The control unit 13 is configured to provide the data stored in the volatile storage unit 12 to the external device when the power supply of the electronic device 1 is shut down or the backup power supply unit 11 supplies power. The control unit 13 is for example a processor such as a central processing unit (CPU). The external device may be an electronic device such as a server, a desktop computer, a notebook computer, a tablet computer, a smart phone, a personal digital assistance, a wearable device, and so on, and may further be a storage means such as an external movable hard disk, an optical disk, a flash memory, and so on.

The communication module 14 is configured to connect the volatile storage unit 12 to the external device so as to provide the data stored in the volatile storage unit 12 to the external device. Preferably, the communication module 14 is a connection circuit including a specific interface for connecting the volatile storage unit 12 to the external device for data transmission. For example, the communication module 14 may be a USB connection circuit including a USB interface, and also be a serial communication circuit including a serial port.

In addition, the backup power supply unit 11 can be further configured to supply power to the communication module 14. In this case, the backup power supply unit 11 can supply power to the volatile storage unit 12, the control unit 13 and the communication module 14 simultaneously when the power supply of the electronic device 1 is shut down. Alternatively, in this case, when the power supply of the electronic device 1 is shut down, the backup power supply unit 11 can supply power to the volatile storage unit 12 and the control unit 13 simultaneously at first; then the control unit 13 controls the backup power supply unit 11 to supply power to the communication module 14 when the control unit 13 detects connection between the external device and the communication module 14.

Alternatively, the communication module 14 can be supplied power by the external device. For example, when the communication module 14 is a USB connection circuit including a USB interface, that is, when the external device is connected to the volatile storage unit 12 through USB connection, the communication module 14 can obtain electricity from the external device through the USB interface, such that data transmission can be performed between the volatile storage unit 12 and the external device.

It can be seen that, in the first embodiment of the present disclosure, the backup power supply unit 11 is provided to supply power to the volatile storage unit 12 and the control unit 13 temporarily when the power supply of the electronic device is shut down suddenly, the data stored in the volatile storage unit 12 is sent by the communication module 14 to the external device during the temporary power supply, such that the external device can store or recover the data and operation state of the electronic device 1 before such power failure, and thus the data in the electronic device 1 can be protected when such power failure happens.

Below, explanations will be given to an electronic device according to a second embodiment of the present disclosure with reference to FIG. 2. FIG. 2 is diagram illustrating configuration of an electronic device 2 according to the second embodiment of the present disclosure. The electronic device 2 according to the second embodiment of the present disclosure may be an electronic device such as a desktop computer, a notebook computer, a tablet computer, a smart phone, a personal digital assistance, a wearable device, and so on.

As shown in FIG. 2, the electronic device 2 according to the second embodiment of the present disclosure and the electronic device 1 according to the first embodiment of the present disclosure are similar in term of hardware configuration, and are different in term of configurations of the backup power supply unit and the control unit and also in that the electronic device 2 comprises a non-volatile storage unit 25. Here, difference between the first embodiment and the second embodiment will be described in detail.

The backup power supply unit 21 is configured to supply power to a volatile storage unit 22, a control unit 23 and a non-volatile storage unit 25 temporarily when a power supply of the electronic device 2 is shut down. As described above, the backup power supply unit 21 is preferably a super capacitor, but the present disclosure is not so limited. The backup power supply unit 21 may further be a power supply capable of supplying power to components of the electronic device, such as a Lithium battery pack, a storage battery pack and so on. In addition, as described above, a time period during which the backup power supply unit 21 supplies power is relatively short and is not a fixed time period, parameters having an effect on the time period during which the backup power supply unit 21 supplies power comprise, but not limited to, amount of data stored in the volatile storage unit 22, processing speed of the control unit 23, and storing speed of the non-volatile storage unit 25. Type and capacity of the backup power supply unit 21 can be selected appropriately by those skilled in the art in consideration of the above respective parameters comprehensively.

The volatile storage unit 22 is configured to store data when being supplied power. The volatile storage unit 22 is for example a memory.

The non-volatile storage unit 25 is configured to store data read out from the volatile storage unit 22. The non-volatile storage unit 25 is for example a hard disk, an optical disk, a flash memory, and so on.

The control unit 23 is configured to read out data from the volatile storage unit 22 and write the data into the non-volatile storage unit 25 when the power supply of the electronic device 2 is shut down or the backup power supply unit 21 supplies power; and to read out the data from the non-volatile storage unit 25, write the data into the volatile storage unit 22 and selectively delete the data in the non-volatile storage unit 25 when the power supply of the electronic device 2 is recovered. Therefore, data in the memory of the electronic device 2 can be stored into the non-volatile storage unit 25 when the power supply of the electronic device 2 is shut down, and then the data can be recovered to the memory when the power supply of the electronic device 2 is recovered, such that the data in the electronic device can be protected when such power failure happens. The control unit 23 is for example a processor such as a central processing unit (CPU).

The control unit 23 can further be configured to provide the data in the non-volatile storage unit 25 to the external device, such that the data and operation state of the electronic device 2 before such power failure can be recovered by the external device. The external device may be an electronic device such as a server, a desktop computer, a notebook computer, a tablet computer, a smart phone, a personal digital assistance, a wearable device, and so on.

The communication module 24 is configured to connect the non-volatile storage unit 25 to the external device so as to provide the data stored in the non-volatile storage unit 25 to the external device. Preferably, the communication module 24 is a connection circuit including a specific interface for connecting the non-volatile storage unit 25 to the external device for data transmission. For example, the communication module 24 may be a USB connection circuit including a USB interface, and also be a serial communication circuit including a serial port.

Electricity of the non-volatile storage unit 25 can come from the backup power supply unit 21 when the control unit 23 controls to provide the data in the non-volatile storage unit 25 to the external device. Alternatively, the electricity of the non-volatile storage unit 25 can also come from the external device, and the communication module 24 can be further configured to supply electricity of the external device to the non-volatile storage unit 25 in this case.

Furthermore, the communication module 24 can be further configured to connect the volatile storage unit 22 to the external device, so as to provide the data stored in the volatile storage unit 22 to the external device. In this case, the control unit 23 controls to read out and write the data in the volatile storage unit 22 into the non-volatile storage unit 25 on one hand, and controls to provide the data in the volatile storage unit 22 to the external device on the other hand. The above two operations can be performed simultaneously, for example, in a case where the external device is connected to the communication module 24 in advance, the control unit 23 begins to perform the above two operations simultaneously when the power supply of the electronic device 2 is shut down. Alternatively, the above two operations can also be performed separately, for example, in a case where the external device is not connected to the communication module 24 in advance, when the power supply of the electronic device 2 is shut down, the control unit 23 controls to read out and write the data in the volatile storage unit 22 into the non-volatile storage unit 25 at first, assuming that such read-out procedure lasts 10 seconds and that the external device is connected to the communication module 24 at the 8th second, the control unit 23 at this time controls to provide the data in the volatile storage unit 22 to the external device, and the data in the volatile storage unit 22 has been already read out and written into the non-volatile storage unit 25 totally at the end of the 10 seconds. Next, the backup power supply unit 21 can maintain supplying power to the volatile storage unit 22, and the control unit 23 controls to provide part of the data in the volatile storage unit 22 which are not provided to the external device yet to the external device continuously; alternatively, the backup power supply unit 21 stops supplying power to the volatile storage unit 22, and the control unit 23 controls to provide the part of the data to the external device from the non-volatile storage unit 25.

Therefore, according to the second embodiment of the present disclosure, the electronic device 2 can store the data in the volatile storage unit 22 into the non-volatile storage unit 25 when the power supply of the electronic device 2 is shut down suddenly, and then recover the data to the volatile storage unit 22 and thus the data and the operation state of the electronic device 2 before such power failure when the power supply of the electronic device 2 is recovered, such that the data in the electronic device 2 can be protected when such power failure happens.

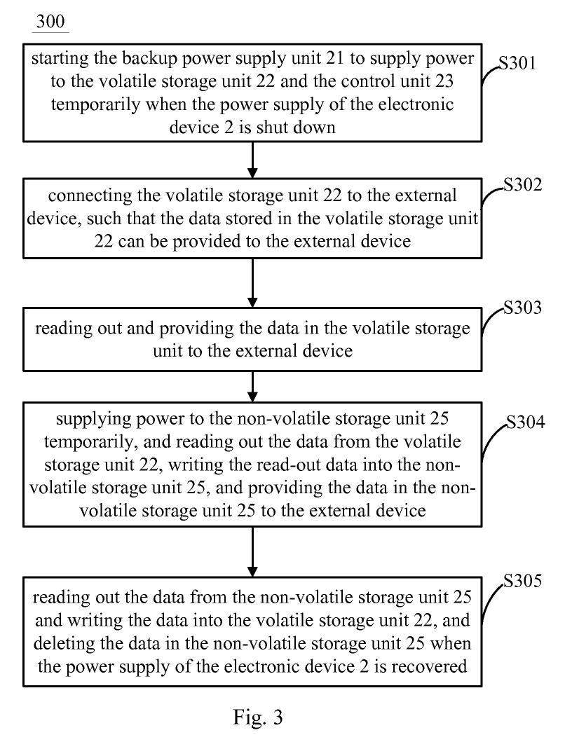

Below, explanations will be given to a power failure protection method according to the embodiments of the present disclosure with reference to FIG. 3.

FIG. 3 is a flowchart illustrating a power failure protection method 300 applied to an electronic device according to the embodiments of the present disclosure. For sake of convenience, the power failure protection method 300 will be described below in combination with the respective components of the electronic device 2 as shown in FIG. 2, and detailed explanations for the respective components will be omitted.

As shown in FIG. 3, at step S301, when the power supply of the electronic device 2 is shut down, the backup power supply unit 21 is started to supply power to the volatile storage unit 22 and the control unit 23 temporarily.

The backup power supply unit 21 supplies power only during power failure protection operation of the electronic device 2, and stops supplying power when the electronic device 2 performs the power failure protection operation completely, that is, the external device has received all of data in the volatile storage unit 22. Parameters, which affects a time period of the power failure protection operation by the electronic device 2, comprise amount of data stored in the volatile storage unit 22, processing speed of the control unit 23, data receiving speed of an external device, and so on.

At step S302, the volatile storage unit 22 is connected to the external device, such that the data stored in the volatile storage unit 22 can be provided to the external device.

Particularly, the communication module 24 connects the volatile storage unit 22 to the external device. Electricity of the communication module 24 can come from the backup power supply unit 21. In this case, at the step S302, the backup power supply unit 21 supplies power to the communication module 24 when the volatile storage unit 22 is connected to the external device through the communication module 24. It should be noted that the backup power supply unit 21 should maintain supplying power to the volatile storage unit 22 and the control unit 23 at the step S302. Alternatively, at the step S301, the backup power supply unit 21 can also supply power to the volatile storage unit 22, the control unit 23 and the communication module 24 temporarily.

Alternatively, the electricity of the communication module 24 can come from the external device. In this case, at the step S302, the external device supplies power to the communication module 24. For example, when the communication module 24 is a USB connection circuit including a USB interface, that is, when the external device is connected to the volatile storage unit 22 through USB connection, the communication module 24 can obtain electricity from the external device through the USB interface, such that data transmission can be performed between the volatile storage unit 22 and the external device.

At step S303, the data in the volatile storage unit is read out and provided to the external device.

Particularly, the control unit 23 controls to read out the data in the volatile storage unit 22 and provide the data to the external device through the communication module 24. It should be noted that the backup power supply unit 21 maintains supplying power to the volatile storage unit 22 and the control unit 23 at the step S303. In addition, the backup power supply unit 21 also maintains supplying power to the communication module 24 in a case where the electricity of the communication module 24 comes from the backup power supply unit 21.

It can be seen that, in the power failure protection method 300 according to the embodiments of the present disclosure, the backup power supply unit 21 is provided to supply power to the volatile storage unit 22 and the control unit 23 temporarily when the power supply of the electronic device is shut down suddenly, and the data in the volatile storage unit 22 is sent by the communication module 24 to the external device during the temporary power supply, such that the external device can store or recover the data and operation state of the electronic device 1 after such power failure, that is, the data in the electronic device 2 can be acquired and protected when such power failure happens, and thus operations on the electronic device 1 can be performed continuously on the electronic device 2.

Furthermore, in the power failure protection method 300 according to the embodiments of the present disclosure, the following steps are performed.

At step S304, the non-volatile storage unit 25 is supplied power temporarily, and the data is read out from the volatile storage unit 22 and written into the non-volatile storage unit 25, and the data in the non-volatile storage unit 25 is provided to the external device.

Particularly, the non-volatile storage unit 25 is arranged in the electronic device 2. The non-volatile storage unit 25 is for example a hard disk, an optical disk, a flash memory, and so on. The backup power supply unit 21 supplies power to the non-volatile storage unit 25 temporarily when a power supply of the electronic device 2 is shut down or the backup power supply unit 21 supplies power. The control unit 23 controls to read out the stored data from the volatile storage unit 22 and write the data into the non-volatile storage unit 25, and the control unit 23 controls to write the data in the non-volatile storage unit 25 to the external device.

The communication module 24 connects the non-volatile storage unit 25 to the external device so as to provide the data stored in the non-volatile storage unit 25 to the external device. Preferably, the communication module 24 is a connection circuit including a specific interface. For example, the communication module 24 may be a USB connection circuit including a USB interface, and also be a serial communication circuit including a serial port. When the control unit 23 controls to provide the data in the non-volatile storage unit 25 to the external device, the control unit 23 controls that the non-volatile storage unit 25 is supplied power by the electricity supplied from the external device.

At step S305, when the power supply of the electronic device 2 is recovered, the data is read out from the non-volatile storage unit 25 and is written into the volatile storage unit 22, and the data in the non-volatile storage unit 25 is deleted.

Although the power failure protection method 300 according to the embodiments of the present disclosure illustrates the above respective steps in order, the embodiments of the present disclosure are not so limited. Particularly, the operation at the step S303 and the operation at the step S305 can be performed simultaneously, that is, the non-volatile storage unit 25 is supplied power and the data in the volatile storage unit 22 is read out and written into the non-volatile storage unit 25 while the data in the volatile storage unit 22 is provided to the external device. For example, in a case where the external device is connected to the communication module 24 in advance, the control unit 23 begins to perform the above two operations simultaneously when the power supply of the electronic device 2 is shut down. Alternatively, the operation at the step S303 and the operation at the step S305 can also be performed separately, for example, in a case where the external device is not connected to the communication module 24 in advance, when the power supply of the electronic device 2 is shut down, the control unit 23 controls to read out and write the data in the volatile storage unit 22 into the non-volatile storage unit 25 at first, assuming that such read-out procedure lasts 10 seconds and that the external device is connected to the communication module 24 at the 8th second, the control unit 23 at this time controls to provide the data in the volatile storage unit 22 to the external device, and the data in the volatile storage unit 22 has been already read out and written into the non-volatile storage unit 25 totally at the end of the 10 seconds. Next, the backup power supply unit 21 can maintain supplying power to the volatile storage unit 22, and the control unit 23 controls to provide part of the data in the volatile storage unit 22 which are not provided to the external device yet to the external device continuously; alternatively, the backup power supply unit 21 stops supplying power to the volatile storage unit 22, and the control unit 23 controls to provide the part of the data to the external device from the non-volatile storage unit 25.

For example, according to the embodiments of the present disclosure, a plurality of virtual machines are running on the electronic device, and virtual machine data of the plurality of virtual machines can be moved to the external device when the electronic device malfunctions. Each of the virtual machines can logically possess separate hardware resources such as a separate processor, a separate memory, a separate hard disk, a separate network interface and so on, and thus applications being executed on each of the virtual machines can be executed in a same physical electronic device but possess separate running environments, thus increasing utilization of the hardware resources. When the electronic device cannot operate normally due to abnormal condition, all of the applications being executed on any of the virtual machines running on the electronic device will be affected and thus cannot operate normally.

However, it should be understood that each of the applications being executed on any of the virtual machines will occupy a memory space in the electronic device, and data of the application is stored in the memory space. When the power supply of the electronic device is shut off abnormally, the data in the memory space will be lost.

In this case, at the step S303, the virtual machine data and indication information of the virtual machine data are read out and provided to the external device through the communication module.

In the embodiments of the present disclosure, the virtual machine data is data used by at least one virtual machine running on a second electronic device, and the indication information of the virtual machine data is used for indicating a corresponding relationship between the virtual machine data and the virtual machine and indicating order of storage of the virtual machine data. Therefore, for each piece of the virtual machine data, the virtual machine to which this piece of the virtual machine data belongs can be determined according to the indication information of the virtual machine data, and meanwhile the order of storage of the virtual machine data belonging to a same virtual machine can also be determined according to the indication information of the virtual machine data.

Here, the indication information of the virtual machine data can comprise virtual machine identification information and storage order identification information, the virtual machine identification information is configured to indicate the virtual machine to which a piece of the virtual machine data belongs, and the storage order identification information is configured to indicate the storage order of the virtual machine data belonging to a same virtual machine.

The virtual machine identification information and the storage order identification information can be represented by binary data having a plurality of bits. For example, the virtual machine identification information and the storage order identification information can be represented by 8-bit binary data and can be stored in the memory. For example, when a first virtual machine stores its virtual machine data in the memory for the first time, a first 8-bits in a first memory page where the virtual machine data is located is used as the virtual machine identification information, for example, 0000 0001, and a second 8-bits (that is, the 9th bit to the 16th bit) is used as the storage order identification information, for example, 0000 0010, as shown in the following table 1. In the following table 1, the virtual machine data 1 represents first data of the first virtual machine.

TABLE I

| Memory | Virtual machine identification | | | | | | | | Storage data identification | | | | | | | | |
|---|---|---|---|---|---|---|---|---|---|---|---|---|---|---|---|---|---|
| page | information | | | | | | | | information | | | | | | | | Stored data |
| page I | 0 | 0 | 0 | 0 | 0 | 0 | 0 | I | 0 | 0 | 0 | 0 | 0 | 0 | I | 0 | Virtual |
| | | | | | | | | | | | | | | | | | machine data I |
| page 2 | 0 | 0 | 0 | 0 | 0 | 0 | 0 | I | 0 | 0 | 0 | 0 | 0 | 0 | I | I | Virtual |
| | | | | | | | | | | | | | | | | | machine data 2 |
| page 3 | 0 | 0 | 0 | 0 | 0 | 0 | 0 | I | 0 | 0 | 0 | 0 | 0 | I | 0 | 0 | Virtual |
| | | | | | | | | | | | | | | | | | machine data 3 |
| . . . | | | | | | | | | | | | | | | | | |
| page n | | | | | | | | | | | | | | | | | |

In this way, when the virtual machine data and the indication information of the virtual machine data are acquired through the communication module, the virtual machine data of each of the virtual machines can be recovered on a first electronic device based on the indication information of the virtual machine data.

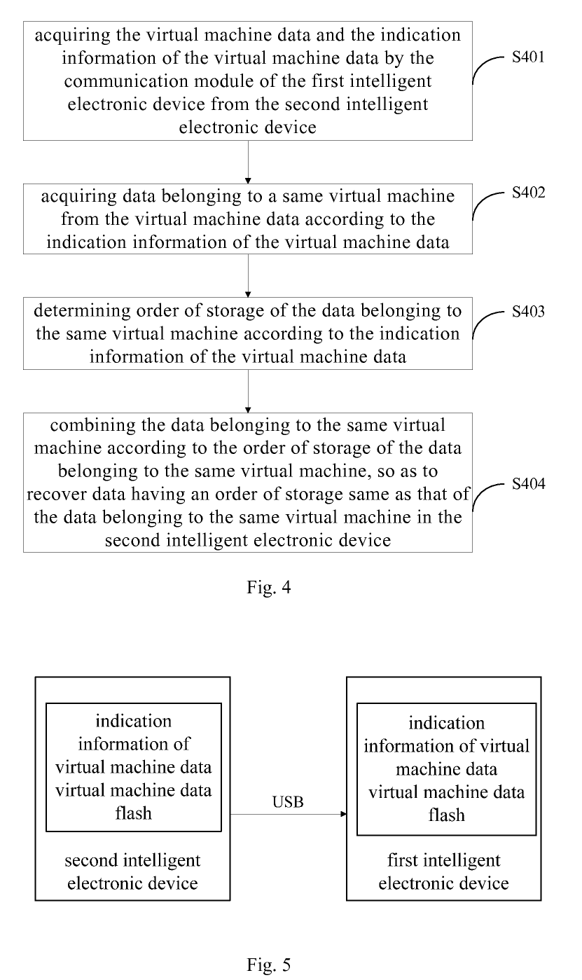

Below, a data recovery method of virtual machine according to the embodiments of the present disclosure will be described with reference to FIG. 4. In FIG. 4, the first electronic device is an electronic device being operating normally, that is, the above external device, the second electronic device is an electronic device which malfunctions, and the data in the second electronic device is recovered to the first electronic device. The data recovery method in FIG. 4 is applied to the first electronic device.

At step S401, the virtual machine data and the indication information of the virtual machine data are acquired by the communication module of the first electronic device from the second electronic device.

In the embodiments of the present disclosure, the communication module is a module through which the first electronic device and the second electronic device communicate, and the first electronic device acquires the virtual machine data and the indication information of the virtual machine data from the second electronic device through the communication between the first electronic device and the second electronic device.

Commonly, the second electronic device prescribes that which communication module should be used to communicate with a corresponding communication module in the first electronic device in advance. For example, the second electronic device prescribes that a Universal Serial Bus (USB) module should be used to communicate with a USB module in the first electronic device in advance, such that the first electronic device can acquire the virtual machine data and the indication information of the virtual machine data from the second electronic device, detailed explanations will be given with reference to FIG. 5.

For example, the second electronic device copies the virtual machine data and the indication information of the virtual machine data to flash in the memory, such that the first electronic device can acquire the virtual machine data and the indication information of the virtual machine data from the flash in the second electronic device through a USB interface, and stores the virtual machine data and the indication information of the virtual machine data into its own flash.

The step S401 can correspond to the step S303 in FIG. 3, or can correspond to the steps S303 and S304 in FIG. 3.

For example, at the step S401, the backup power supply unit 21 of the second electronic device maintains supplying power to the volatile storage unit 22 and the control unit 23, and further maintains supplying power to the communication module 24.

Alternatively, for example, at the step S401, the backup power supply unit 21 of the second electronic device maintains supplying power to the volatile storage unit 22, the non-volatile storage unit 25 and the control unit 23, and further maintains supplying power to the communication module 24.

In order to further increase possibility of data recovery, the first electronic device can receive through the communication module the virtual machine data and the indication information of the virtual machine data sent by the second electronic device actively before the power supply of the second electronic device is shut down, such that possibility can be reduced that the first electronic device cannot acquire all of the virtual machine data and the indication information of the virtual machine data after the power supply of the second electronic device is shut down and before an emergency power supply is exhausted or terminates power supplying, and such that the first electronic device can receive all of the virtual machine data and the indication information of the virtual machine data stored in and sent actively by the second electronic device. The emergency power supply may be a device for supplying power to the memory of the second electronic device after the power supply of the second electronic device is shut down, for example, the backup power supply unit 21.

In the embodiments of the present disclosure, the second electronic device can determine a power-supply-shut-down timing by detecting conditions under which the power supply of the second electronic device will be shut down, such that the second electronic device can send the virtual machine data and the indication information of the virtual machine data before the power-supply-shut-down timing. Of course, the second electronic device can send the virtual machine data and the indication information of the virtual machine data after receiving of a data sending request from the first electronic device.

At step S402, data belonging to a same virtual machine is acquired from the virtual machine data according to the indication information of the virtual machine data.

At step S403, order of storage of the data belonging to the same virtual machine is determined according to the indication information of the virtual machine data.

At step S404, the data belonging to the same virtual machine is combined according to the order of storage of the data belonging to the same virtual machine, so as to recover data having an order of storage same as that of the data belonging to the same virtual machine in the second electronic device.

As described above, the indication information of the virtual machine data is configured to indicate a corresponding relationship between the virtual machine data and the virtual machine and indicate order of storage of the virtual machine data, so the virtual machine to which a piece of the virtual machine data belongs can be determined according to the indication information of the virtual machine data, and meanwhile the order of storage of the virtual machine data belonging to a same virtual machine can also be determined, according to the indication information of the virtual machine data. Then, the virtual machine data belonging to a same virtual machine can be combined based on the order of storage of the virtual machine data belonging to the same virtual machine, such that data having an order of storage same as that of the data belonging to the same virtual machine in the second electronic device can be recovered.

For example, the virtual machine data 1 located at the flash address 1 is the data of the first virtual machine having a storage order of 1, the virtual machine data 2 located at the flash address 2 is the data of the first virtual machine having a storage order of 2, and the data having the storage order of 2 follows the data having the storage order of 1 when being combined, such that the data having the storage order of 1 and the data having the storage order of 2 of the first virtual machine have the storage order of 1 and the storage order of 2 in the first electronic device, that is, the storage order of the virtual machine data 1 and 2 on the first electronic device is same as that on the second electronic device.

With the above technical solutions provided in the embodiments of the present disclosure, the virtual machine data and the indication information of the virtual machine data can be acquired by the communication module of the first electronic device from the second electronic device; then, the virtual machine data belonging to a same virtual machine can be acquired from the virtual machine data and the order of storage of the virtual machine data belonging to the same virtual machine can also be determined, according to the indication information of the virtual machine data; at last, the virtual machine data belonging to the same virtual machine can be combined based on the order of storage of the virtual machine data belonging to the same virtual machine, such that data having an order of storage same as that of the data belonging to the same virtual machine in the second electronic device can be recovered.

Below, procedures for acquiring data belonging to a same virtual machine and determining storage order thereof will be explained by taking a case that the indication information of the virtual machine data comprises virtual machine identification information and storage order identification information each of which is represented by binary data having a plurality of bits as an example.

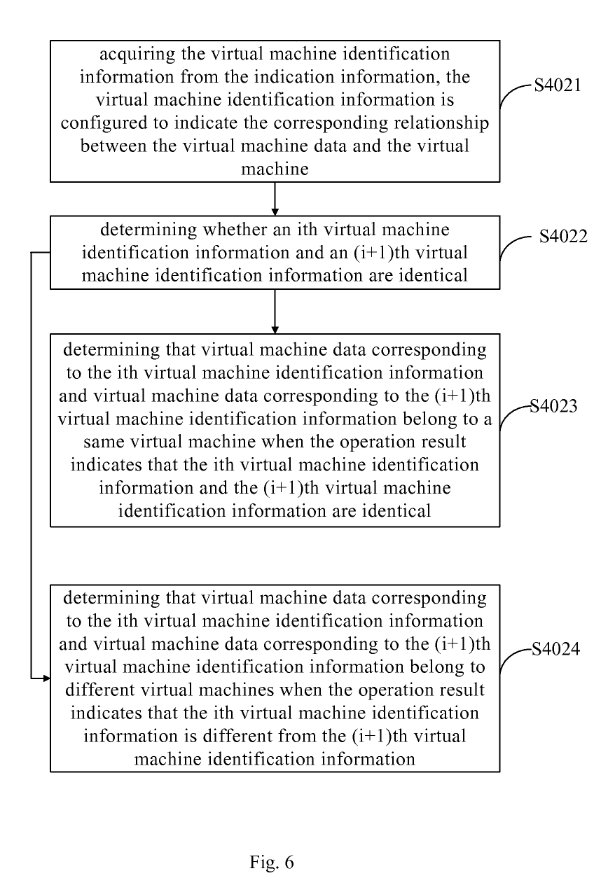

With reference to FIG. 6, the procedure for acquiring data belonging to a same virtual machine in the step S402 in the data recovery method provided in the embodiments of the present disclosure is illustrated.

At step S4021, the virtual machine identification information is acquired from the indication information. The virtual machine identification information is configured to indicate the corresponding relationship between the virtual machine data and the virtual machine, that is, the virtual machine identification information can indicate the virtual machine to which a piece of the virtual machine data belongs. Therefore, the data belonging to a same virtual machine can be determined according to the virtual machine identification information.

At step S4022, it is determined whether an ith virtual machine identification information and an (i+1)th virtual machine identification information are identical.

For example, an AND operation may be performed on the ith virtual machine identification information and the (i+1)th virtual machine identification information. Particularly, for example, each virtual machine identification information is represented by binary data with n bits, an AND operation is performed on each (the jth bit, 0≦j≦n−1) of the n bits of the ith virtual machine identification information and its corresponding bit of the (i+1)th virtual machine identification information sequentially, such that an operation result can be obtained for the vector AND operation on the ith virtual machine identification information and the (i+1)th virtual machine identification information, where 1≦i≦m, and m is the total number of the virtual machine identification information.

In the embodiments of the present disclosure, when it is determined whether the virtual machine data belongs to a same virtual machine, it is required to perform an AND operation on any two of the m pieces of virtual machine identification information, and then to determine the virtual machines to which the virtual machine data corresponding respectively to the m pieces of virtual machine identification information belongs.

Particularly, when an AND operation is performed on the ith virtual machine identification information and the (i+1)th virtual machine identification information, it is required to perform an AND operation on each (the jth bit, 0≦j≦n−1) of the n bits of the ith virtual machine identification information and its corresponding bit of the (i+1)th virtual machine identification information sequentially. For example, the ith virtual machine identification information is 0000 0001, and the (i+1)th virtual machine identification information is 0000 0001, the operation result is 0000 0001 after an AND operation is performed from 0th bit to 7th bit of the ith virtual machine identification information and the (i+1)th virtual machine identification information sequentially. Here, the vector AND operation is used for determining whether a value of each bit of the ith virtual machine identification information and a value of a corresponding bit of the (i+1)th virtual machine identification information are identical.

It can be seen from the operation result 0000 0001 that the operation result is identical to the ith virtual machine identification information and the (i+1)th virtual machine identification information, which means that the ith virtual machine identification information is identical to the (i+1)th virtual machine identification information, and that a piece of virtual machine data corresponding to the ith virtual machine identification information and a piece of virtual machine data corresponding to the (i+1)th virtual machine identification information belong to a same virtual machine.

If the (i+1)th virtual machine identification information is 0000 0010, an operation result is 0000 0000 when an AND operation is performed on the ith virtual machine identification information and the (i+1)th virtual machine identification information. It can be seen that the operation result is different from both the ith virtual machine identification information and the (i+1)th virtual machine identification information, which means that the ith virtual machine identification information is different from the (i+1)th virtual machine identification information, and that a piece of virtual machine data corresponding to the ith virtual machine identification information and a piece of virtual machine data corresponding to the (i+1)th virtual machine identification information do not belong to a same virtual machine.

At step S4023, when the operation result indicates that the ith virtual machine identification information and the (i+1)th virtual machine identification information are identical, it is determined that a piece of virtual machine data corresponding to the ith virtual machine identification information and a piece of virtual machine data corresponding to the (i+1)th virtual machine identification information belong to a same virtual machine.

At step S4024, when the operation result indicates that the ith virtual machine identification information is different from the (i+1)th virtual machine identification information, it is determined that a piece of virtual machine data corresponding to the ith virtual machine identification information and a piece of virtual machine data corresponding to the (i+1)th virtual machine identification information belong to different virtual machines.

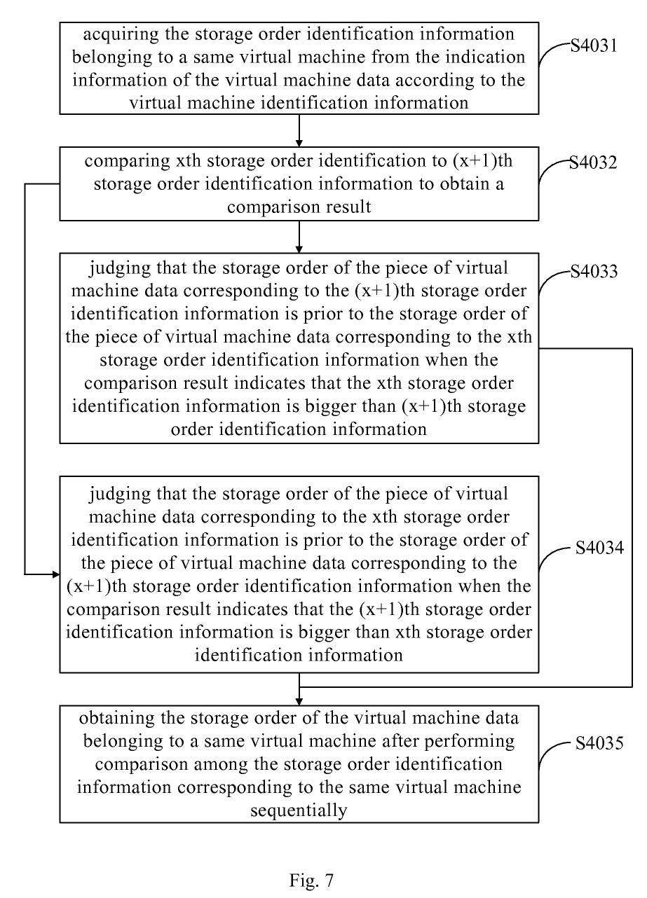

After the virtual machine data belonging to a same virtual machine is acquired, order of storage of the virtual machine data can be further determined according to the indication information of the virtual machine data, as shown in FIG. 7. FIG. 7 is a flowchart illustrating the step S403 in the data recovery method provided in the embodiments of the present disclosure for identifying order of storage of the virtual machine data belonging to a same virtual machine.

At step S4031, the storage order identification information belonging to a same virtual machine is acquired from the indication information of the virtual machine data according to the virtual machine identification information. The storage order identification information is used to identify order of storage of data belonging to the same virtual machine.

At step S4032, an order relationship is determined between a xth piece of storage order identification information and a (x+1)th piece of storage order identification information belonging to the same virtual machine.

For example, the storage order identification information can be represented by binary data having k bits, a total number of the storage order identification information belonging to the same virtual machine is z, each bit of the xth piece of storage order identification information and a corresponding bit of the (x+1)th piece of storage order identification information are compared from a highest bit to a lowest bit to obtain a comparison result, where 1≦≦z.

In the embodiments of the present disclosure, when determining the order of storage of the virtual machine data belonging to a same virtual machine, it is required to compare any two of the z pieces of storage order identification information, and then to determine the order of storage of the virtual machine data corresponding to all of the z pieces of storage order identification information.

For example, when the xth piece of storage order identification information is compared to the (x+1)th piece of storage order identification information, it is required to compare each bit of the xth piece of storage order identification information and a corresponding bit of the (x+1)th piece of storage order identification information from a highest bit to a lowest bit sequentially. During comparison, when a yth bit of a piece of storage order identification information is bigger than a yth bit of another piece of storage order identification information, the storage order identification information the yth bit of which is the bigger is used as a comparison result. When the comparison result is identical to a piece of storage order identification information, it is indicated that the piece of storage order identification information which is identical to the comparison result is bigger than another one, and that the order of storage of the virtual machine data corresponding to these two pieces of storage order identification information is as follows: the piece of virtual machine data corresponding to the piece of storage order identification information which is identical to the comparison result follows the piece of virtual machine data corresponding to the another piece of storage order identification information.

Particularly, the xth piece of storage order identification information is 0000 0001, and the (x+1)th piece of storage order identification information is 0000 0010, it is determined that a 6th bit of the (x+1)th piece of storage order identification information is bigger than a 6th bit of the xth piece of storage order identification information after comparing each bit of the xth piece of storage order identification information to a corresponding bit of the (x+1)th piece of storage order identification information sequentially from a 0th bit (the highest bit), the operation result is 0000 0010. Therefore, the piece of virtual machine data corresponding to the (x+1)th piece of storage order identification information follows the piece of virtual machine data corresponding to the xth piece of storage order identification information.

At step S4033, when the comparison result indicates that the xth piece of storage order identification information is bigger than (x+1)th piece of storage order identification information, it is determined that the storage order of the piece of virtual machine data corresponding to the (x+1)th piece of storage order identification information is prior to the storage order of the piece of virtual machine data corresponding to the xth piece of storage order identification information.

At step S4034, when the comparison result indicates that the (x+1)th piece of storage order identification information is bigger than xth piece of storage order identification information, it is determined that the storage order of the piece of virtual machine data corresponding to the xth piece of storage order identification information is prior to the storage order of the piece of virtual machine data corresponding to the (x+1)th piece of storage order identification information.

At step S4035, the storage order of the virtual machine data belonging to a same virtual machine is obtained after performing comparison among the storage order identification information corresponding to the same virtual machine sequentially.

Furthermore, the data recovery method provided in the embodiments of the present disclosure can further comprise: supplying power to the second electronic device through a communication interface of the first electronic device, the communication interface being an interface through which the communication module is connected to the second electronic device. In this way, when the second electronic device malfunctions, the second electronic device can be supplied power through the communication interface, such that the second electronic device can operate with power supplied from the first electronic device. During such power supplying period, the first electronic device acquires the virtual machine data and the indication information of the virtual machine data from the second electronic device, and thus possibility that the first electronic device cannot acquire all of the virtual machine data and the indication information of the virtual machine data is reduced.

In the embodiments of the present disclosure, the first electronic device can supply power to all hardware components in the second electronic device. Of course, in consideration of limitation of electricity provided by the first electronic device, the first electronic device can preferably supply power to the hardware components in the second electronic device related to storage of the virtual machine data and the indication information of the virtual machine data, for example, preferably supply power to the memory and flash in the memory in the second electronic device. In this case, the virtual machine data and the indication information of the virtual machine data can be stored in a first storage region in the memory of the second electronic device, and the first electronic device acquires the virtual machine data and the indication information of the virtual machine data from the first storage region through the USB interface, and stores the virtual machine data and the indication information of the virtual machine data into its own memory. Here, the first storage region is a storage region different from the flash in the memory. Of course, in this case, the virtual machine data and the indication information of the virtual machine data can be stored in the flash in the second electronic device and can be transmitted to flash in the first electronic device through the USB interface.

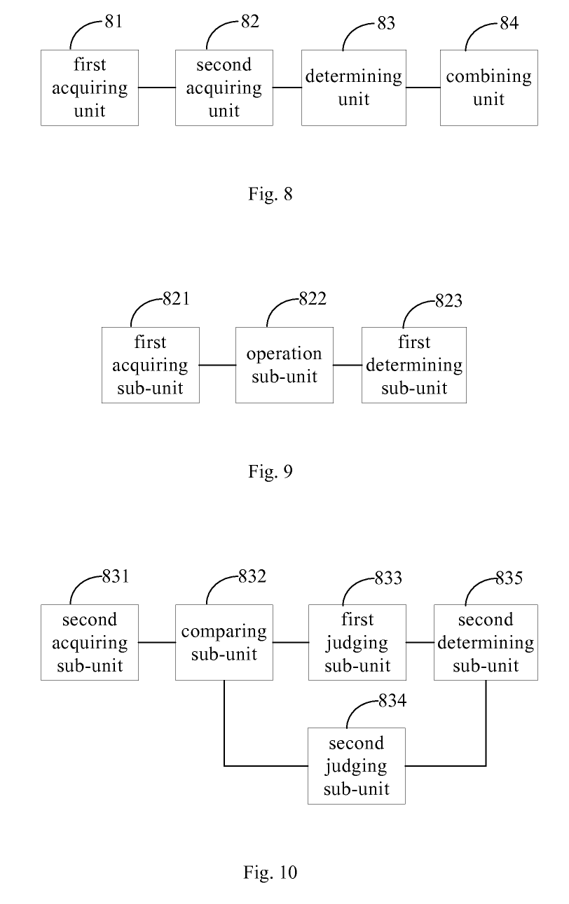

Corresponding to the above method embodiment, there is further provided a data recovery apparatus applied to the above first electronic device. FIG. 8 is a schematic diagram illustrating structure of the data recovery apparatus applied to the first electronic device. The data recovery apparatus can comprises a first acquiring unit 81, a second acquiring unit 82, a determining unit 83 and a combining unit 84.

The first acquiring unit 81 is configured to acquire the virtual machine data and the indication information of the virtual machine data through the communication module of the first electronic device from the second electronic device.

In the embodiments of the present disclosure, the virtual machine data is data used by at least one virtual machine running on the second electronic device, and the indication information of the virtual machine data is used for indicating a corresponding relationship between the virtual machine data and the virtual machine and indicating order of storage of the virtual machine data. Therefore, for each piece of the virtual machine data, the virtual machine to which this piece of the virtual machine data belongs can be determined according to the indication information of the virtual machine data, and meanwhile the order of storage of the virtual machine data belonging to a same virtual machine can also be determined according to the indication information of the virtual machine data.

Here, the indication information of the virtual machine data can comprise virtual machine identification information and storage order identification information, the virtual machine identification information is configured to indicate the virtual machine to which a piece of the virtual machine data belongs, and the storage order identification information is configured to indicate the storage order of the virtual machine data belonging to a same virtual machine. The virtual machine identification information and the storage order identification information can be represented by binary data having a plurality of bits, as shown in the above Table 1, detailed explanations will be omitted in this embodiment of the present disclosure.

Once the first acquiring unit 81 acquires the virtual machine data and the indication information of the virtual machine data through the communication module, the data recovery apparatus can recover the virtual machine data of each of the virtual machines on the first electronic device based on the indication information of the virtual machine data.

In the embodiments of the present disclosure, the communication module is a module through which the first electronic device and the second electronic device communicate, and the first electronic device can acquire the virtual machine data and the indication information of the virtual machine data from the second electronic device through the communication between the first electronic device and the second electronic device.

Commonly, the second electronic device prescribes that which communication module should be used to communicate with a corresponding communication module in the first electronic device in advance. For example, the second electronic device prescribes that a Universal Serial Bus (USB) module should be used to communicate with a USB module in the first electronic device in advance, such that the first electronic device can acquire the virtual machine data and the indication information of the virtual machine data from the second electronic device, detailed operations can be obtained with reference to FIG. 5.

For example, the second electronic device copies the virtual machine data and the indication information of the virtual machine data to the flash in the memory, such that the first electronic device can acquire the virtual machine data and the indication information of the virtual machine data from the flash in the second electronic device through the USB interface, and stores the virtual machine data and the indication information of the virtual machine data into its own flash.

In order to further increase possibility of data recovery, the first acquiring unit 81 can receive through the communication module the virtual machine data and the indication information of the virtual machine data sent by the second electronic device actively before the power supply of the second electronic device is shut down, such that possibility can be reduced that the first electronic device cannot acquire all of the virtual machine data and the indication information of the virtual machine data after the power supply of the second electronic device is shut down and before an emergency power supply is exhausted or terminates power supplying, and such that the first electronic device can receive all of the virtual machine data and the indication information of the virtual machine data stored in and sent actively by the second electronic device. The emergency power supply may be a device for supplying power to the memory of the second electronic device after the power supply of the second electronic device is shut down, for example, the backup power supply unit 21.

In the embodiments of the present disclosure, the second electronic device can determine a power-supply-shut-down timing by detecting conditions under which the power supply of the second electronic device will be shut down, such that the second electronic device can send the virtual machine data and the indication information of the virtual machine data before the power-supply-shut-down timing. Of course, the second electronic device can send the virtual machine data and the indication information of the virtual machine data after receiving of a data sending request from the first electronic device.

The second acquiring unit 82 acquires data belonging to a same virtual machine from the virtual machine data according to the indication information of the virtual machine data.

The determining unit 83 determines order of storage of the data belonging to the same virtual machine according to the indication information of the virtual machine data.

The combining unit 84 combines the data belonging to the same virtual machine is combined according to the order of storage of the data belonging to the same virtual machine, so as to recover data having an order of storage same as that of the data belonging to the same virtual machine in the second electronic device

As described above, in the embodiments of the present disclosure, the indication information of the virtual machine data is configured to indicate a corresponding relationship between the virtual machine data and the virtual machine and indicate order of storage of the virtual machine data, so the virtual machine to which a piece of the virtual machine data belongs can be determined according to the indication information of the virtual machine data, and meanwhile the order of storage of the virtual machine data belonging to a same virtual machine can also be determined according to the indication information of the virtual machine data. Then, the virtual machine data belonging to a same virtual machine can be combined based on the order of storage of the virtual machine data belonging to the same virtual machine, such that data having an order of storage same as that of the data belonging to the same virtual machine in the second electronic device can be recovered.

For example, the virtual machine data 1 located at the flash address 1 is the data of the first virtual machine having a storage order of 1, the virtual machine data 2 located at the flash address 2 is the data of the first virtual machine having a storage order of 2, and the data having the storage order of 2 follows the data having the storage order of 1 when being combined, such that the data having the storage order of 1 and the data having the storage order of 2 of the first virtual machine have the storage order of 1 and the storage order of 2 in the first electronic device, that is, the storage order of the virtual machine data 1 and 2 on the first electronic device is same as that on the second electronic device.

With the above technical solutions provided in the embodiments of the present disclosure, the virtual machine data and the indication information of the virtual machine data can be acquired through the communication module of the first electronic device from the second electronic device; then, the virtual machine data belonging to a same virtual machine can be acquired from the virtual machine data and the order of storage of the virtual machine data belonging to the same virtual machine can also be determined according to the indication information of the virtual machine data; at last, the virtual machine data belonging to the same virtual machine can be combined based on the order of storage of the virtual machine data belonging to the same virtual machine, such that data having an order of storage same as that of the data belonging to the same virtual machine in the second electronic device can be recovered.

FIG. 9 is a schematic diagram illustrating structure of the second acquiring unit 82 in the data recovery apparatus provided in the embodiments of the present disclosure. The second acquiring unit 82 may comprise a first acquiring sub-unit 821, an operation sub-unit 822 and a first determining sub-unit 823.

The first acquiring sub-unit 821 is configured to acquire the virtual machine identification information from the indication information. The virtual machine identification information is configured to indicate the corresponding relationship between the virtual machine data and the virtual machine, that is, the virtual machine identification information can indicate the virtual machine to which a piece of the virtual machine data belongs. Therefore, the data belonging to a same virtual machine can be determined according to the virtual machine identification information.

The operation sub-unit 822 is configured to determine whether an ith virtual machine identification information and an (i+1)th virtual machine identification information are identical.

For example, each virtual machine identification information is represented by binary data with n bits, an AND operation is performed on each (the jth bit, 0≦j≦n−1) of the n bits of the ith virtual machine identification information and its corresponding bit of the (i+1)th virtual machine identification information sequentially, such that an operation result can be obtained, where 1≦i≦m, and m is the total number of the virtual machine identification information. In the embodiments of the present disclosure, when it is determined whether the virtual machine data belongs to a same virtual machine, it is required to perform an AND operation on any two of the m pieces of virtual machine identification information, and then to determine the virtual machines to which the virtual machine data corresponding respectively to the m pieces of virtual machine identification information belongs.

Particularly, when an AND operation is performed on the ith virtual machine identification information and the (i+1)th virtual machine identification information, it is required to perform an AND operation on each (the jth bit, 0≦j≦n−1) of the n bits of the ith virtual machine identification information and its corresponding bit of the (i+1)th virtual machine identification information sequentially. For example, the ith virtual machine identification information is 0000 0001, and the (i+1)th virtual machine identification information is 0000 0001, the operation result is 0000 0001 after an AND operation is performed from 0th bit to 7th bit of the ith virtual machine identification information and the (i+1)th virtual machine identification information sequentially. Here, the AND operation is used for determining whether a value of each bit of the ith virtual machine identification information and a value of a corresponding bit of the (i+1)th virtual machine identification information are identical.

It can be seen from the operation result 0000 0001 that the operation result is identical to the ith virtual machine identification information and the (i+1)th virtual machine identification information, which means that the ith virtual machine identification information is identical to the (i+1)th virtual machine identification information, and that a piece of virtual machine data corresponding to the ith virtual machine identification information and a piece of virtual machine data corresponding to the (i+1)th virtual machine identification information belong to a same virtual machine.

If the (i+1)th virtual machine identification information is 0000 0010, an operation result is 0000 0000 when an AND operation is performed on the ith virtual machine identification information and the (i+1)th virtual machine identification information. It can be seen that the operation result is different from both the ith virtual machine identification information and the (i+1)th virtual machine identification information, which means that the ith virtual machine identification information is different from the (i+1)th virtual machine identification information, and that a piece of virtual machine data corresponding to the ith virtual machine identification information and a piece of virtual machine data corresponding to the (i+1)th virtual machine identification information do not belong to a same virtual machine.

The first determining sub-unit 823 is configured to determine that a piece of virtual machine data corresponding to the ith virtual machine identification information and a piece of virtual machine data corresponding to the (i+1)th virtual machine identification information belong to a same virtual machine when the operation result indicates that the ith virtual machine identification information and the (i+1)th virtual machine identification information are identical.

The first determining sub-unit 823 is further configured to determine that a piece of virtual machine data corresponding to the ith virtual machine identification information and a piece of virtual machine data corresponding to the (i+1)th virtual machine identification information belong to different virtual machines when the operation result indicates that the ith virtual machine identification information is different from the (i+1)th virtual machine identification information.

FIG. 10 is a schematic diagram illustrating structure of the determining unit in the data recovery apparatus provided in the embodiments of the present disclosure. The determining unit may comprise a second acquiring sub-unit 831, a comparing sub-unit 832, a first judging sub-unit 833, a second judging sub-unit 834 and a second determining sub-unit 835.

The second acquiring sub-unit 831 is configured to acquire the storage order identification information belonging to a same virtual machine from the indication information of the virtual machine data according to the virtual machine identification information. The storage order identification information is used to identify order of storage of data belonging to the same virtual machine.

The comparing sub-unit 832 is configured to acquire an order relationship between a xth piece of storage order identification information and a (x+1)th piece of storage order identification information belonging to the same virtual machine.

For example, the storage order identification information can be represented by binary data having k bits, the total number of the storage order identification information belonging to the same virtual machine is z, each bit of the xth piece of storage order identification information and a corresponding bit of the (x+1)th piece of storage order identification information are compared from a highest bit to a lowest bit to obtain a comparison result, where 1≦x≦z.

In the embodiments of the present disclosure, when determining the order of storage of the virtual machine data belonging to a same virtual machine, it is required to compare any two of the z pieces of storage order identification information, and then to determine the order of storage of the virtual machine data corresponding to all of the z pieces of storage order identification information.

For example, when the xth piece of storage order identification information is compared to the (x+1)th piece of storage order identification information, it is required to compare each bit of the xth piece of storage order identification information and a corresponding bit of the (x+1)th piece of storage order identification information from a highest bit to a lowest bit sequentially. During comparison, when a yth bit of a piece of storage order identification information is bigger than a yth bit of another piece of storage order identification information, the storage order identification information the yth bit of which is the bigger is used as a comparison result. When the comparison result is identical to a piece of storage order identification information, it is indicated that the piece of storage order identification information which is identical to the comparison result is bigger than another one, and that the order of storage of the virtual machine data corresponding to these two pieces of storage order identification information is as follows: the piece of virtual machine data corresponding to the piece of storage order identification information which is identical to the comparison result follows the piece of virtual machine data corresponding to the another piece of storage order identification information.

Particularly, the xth piece of storage order identification information is 0000 0001, and the (x+1)th piece of storage order identification information is 0000 0010, it is determined that a 6th bit of the (x+1)th piece of storage order identification information is bigger than a 6th bit of the xth piece of storage order identification information after comparing each bit of the xth piece of storage order identification information to a corresponding bit of the (x+1)th piece of storage order identification information sequentially from a 0th bit (the highest bit), the operation result is 0000 0010. Therefore, the piece of virtual machine data corresponding to the (x+1)th piece of storage order identification information follows the piece of virtual machine data corresponding to the xth piece of storage order identification information.

The first judging sub-unit 833 is configured to judge that the storage order of the piece of virtual machine data corresponding to the (x+1)th piece of storage order identification information is prior to the storage order of the piece of virtual machine data corresponding to the xth piece of storage order identification information when the comparison result indicates that the xth piece of storage order identification information is bigger than (x+1)th piece of storage order identification information.

The second judging sub-unit 834 is configured to judge that the storage order of the piece of virtual machine data corresponding to the xth piece of storage order identification information is prior to the storage order of the piece of virtual machine data corresponding to the (x+1)th piece of storage order identification information when the comparison result indicates that the (x+1)th piece of storage order identification information is bigger than xth piece of storage order identification information.

The second determining sub-unit 835 obtains the storage order of the virtual machine data belonging to a same virtual machine after comparison is performed among the storage order identification information corresponding to the same virtual machine sequentially.

Furthermore, the data recovery apparatus provided in the embodiments of the present disclosure can further comprise: a power supply unit configured to supply power to the second electronic device through a communication interface of the first electronic device, the communication interface being an interface through which the communication module is connected to the second electronic device. In this way, when the second electronic device malfunctions, the second electronic device can be supplied power through the communication interface, such that the second electronic device can operate with power supplied from the first electronic device. During such power supplying period, the first electronic device acquires the virtual machine data and the indication information of the virtual machine data from the second electronic device, and thus possibility that the first electronic device cannot acquire all of the virtual machine data and the indication information of the virtual machine data is reduced.

In the embodiments of the present disclosure, the first electronic device can supply power to all hardware components in the second electronic device. Of course, in consideration of limitation of electricity provided by the first electronic device, the first electronic device can preferably supply power to the hardware components in the second electronic device related to storage of the virtual machine data and the indication information of the virtual machine data, for example, preferably supply power to the memory and flash in the memory in the second electronic device. In this case, the virtual machine data and the indication information of the virtual machine data can be stored in a first storage region in the memory of the second electronic device, and the first electronic device acquires the virtual machine data and the indication information of the virtual machine data from the first storage region through the USB interface, and stores the virtual machine data and the indication information of the virtual machine data into its own memory. Here, the first storage region is a storage region different from the flash in the memory. Of course, in this case, the virtual machine data and the indication information of the virtual machine data can be stored in the flash in the second electronic device and can be transmitted to flash in the first electronic device through the USB interface.

It should be explained that the respective embodiments of the present disclosure are described in a progressive manner, and difference between the currently discussed embodiment and other embodiments are explained mainly, and the same portion or similar portion among the respective embodiments of the present disclosure are not explained repeatedly. For an embodiment corresponding to an apparatus, explanation for this embodiment is relatively simple as it is similar to an embodiment corresponding to a method and particular operations of similar portions can be obtained with reference to the explanation for the embodiment corresponding to the method.

Finally, it should be explained that, hereinafter, terms indicating relationship such as “first” and “second” are only used to distinguish one entity or operation from another entity or operation, but do not require or mean that such order is actually existed between these entities and operations. Furthermore, terms such as “including”, “comprising” and any other equivalent variations means nonexclusive, such that a process, method, product or device which comprises a series of elements not only comprises the series of elements but also comprises other elements not listed explicitly, or further comprises inherent elements of the process, method, product or device. In case that there is no more limitation, if it is defined the process, method, product or device comprises an element, it is not excluded that there is another same element in the process, method, product or device.

Obviously, those skilled in the art can make various alternations and modifications to the present disclosure without departing the spirit and scope of the present disclosure. As such, if these alternations and modifications of the present disclosure fall into the scope of the claims of the present disclosure as well as the equivalent technique thereof, then the present disclosure intends to include these alternations and modifications.

1. An electronic device comprising:
a backup power supply unit configured to supply power to a volatile storage unit and a control unit temporarily when a power supply of the electronic device is shut down;
the control unit configured to provide data stored in the volatile storage unit to an external device when the power supply of the electronic device is shut down or the control unit is supplied power by the backup power supply unit; and
a communication module configured to connect the volatile storage unit to the external device so as to provide the data stored in the volatile storage unit to the external device.

2. The electronic device according to claim 1, further comprising a non-volatile storage unit configured to store data read out from the volatile storage unit, wherein the backup power supply unit is configured to supply power to the non-volatile storage unit temporarily, and the control unit is further configured to read out the data from the volatile storage unit and write the data into the non-volatile storage unit when the power supply of the electronic device is shut down or the backup power supply unit supplies power; and is further configured to read out the data from the non-volatile storage unit, and write the data into the volatile storage unit when the power supply of the electronic device is recovered.

3. The electronic device according to claim 2, wherein the control unit is further configured to provide the data in the non-volatile storage unit to the external device, and the non-volatile storage unit is supplied power by the external device when the control unit controls to provide the data in the non-volatile storage unit to the external device.

4. The electronic device according to claim 1, wherein virtual machine data and indication information of the virtual machine data stored in the volatile storage unit are provided to the external device through the communication module, the virtual machine data is data used by at least one virtual machine running on the electronic device, and the indication information of the virtual machine data is used for indicating a corresponding relationship between the virtual machine data and the virtual machine and indicating order of storage of the virtual machine data.

5. The electronic device according to claim 1, wherein the backup power supply unit is further configured to supply power to the communication module, or the communication module is supplied power by the external device.

6. A method comprising:
starting a backup power supply scheme to supply power temporarily when a power supply is shut down;
establishing connection to an external device; and
providing data stored in a volatile storage unit to the external device.

7. The method according to claim 6, further comprising:
supplying power to a non-volatile storage unit temporarily, and
reading out the data from the volatile storage unit, writing the read-out data into the non-volatile storage unit, and providing the data in the non-volatile storage unit to the external device.

8. The method according to claim 7, wherein the data is read out from the non-volatile storage unit and written into the volatile storage unit when the power supply is recovered.

9. The method according to claim 7, wherein the non-volatile storage unit is supplied power by the external device when the data in the non-volatile storage unit is provided to the external device.

10. The method according to claim 6, wherein virtual machine data and indication information of the virtual machine data stored in the volatile storage unit are provided to the external device, the virtual machine data is data used by at least one virtual machine running on the electronic device, and the indication information of the virtual machine data is used for indicating a corresponding relationship between the virtual machine data and the virtual machine and indicating order of storage of the virtual machine data.

11. A data recovery method comprising:
acquiring virtual machine data and indication information of the virtual machine data from a second electronic device, the virtual machine data being data used by at least one virtual machine running on the second electronic device, and the indication information of the virtual machine data indicating a corresponding relationship between the virtual machine data and the virtual machine and indicating order of storage of the virtual machine data;
acquiring data belonging to a same virtual machine from the virtual machine data according to the indication information of the virtual machine data; and
combining the data belonging to the same virtual machine according to the indication information of the virtual machine data, so as to recover data having an order of storage same as that of the data belonging to the same virtual machine in the second electronic device.

12. The data recovery method according to claim 11, wherein the acquiring data belonging to a same virtual machine from the virtual machine data according to the indication information of the virtual machine data comprises:
acquiring virtual machine identification information from the indication information, the virtual machine identification information indicating a corresponding relationship between the virtual machine data and the virtual machine;
determining whether an i^{th} virtual machine identification information and an (i+1)^{th} virtual machine identification information are identical, wherein 1≦i≦m, m is a total number of the virtual machine identification information; and
determining that virtual machine data corresponding to the i^{th} virtual machine identification information and virtual machine data corresponding to the (i+1)^{th} virtual machine identification information belong to a same virtual machine when the operation result indicates that the i^{th} virtual machine identification information and the (i+1)^{th} virtual machine identification information are identical.

13. The data recovery method according to claim 11, wherein the combining the data belonging to the same virtual machine according to the indication information of the virtual machine data comprises:
determining order of storage of the data belonging to the same virtual machine according to the indication information of the virtual machine data; and
combining the data belonging to the same virtual machine according to the order of storage of the data belonging to the same virtual machine.

14. The data recovery method according to claim 13, wherein the determining order of storage of the data belonging to the same virtual machine according to the indication information of the virtual machine data comprises:
acquiring storage order identification information belonging to the same virtual machine from the indication information of the virtual machine data according to the virtual machine identification information, the storage order identification information identifying order of storage of data belonging to the same virtual machine;
comparing each bit of a x^{th} storage order identification information and a corresponding bit of a (x+1)^{th} storage order identification information from a highest bit to a lowest bit to obtain a comparison result, wherein 1≦x≦z, and z is a total number of the storage order identification information belonging to the same virtual machine;
judging that the storage order of a piece of virtual machine data corresponding to the (x+1)^{th} storage order identification information is prior to the storage order of a piece of virtual machine data corresponding to the x^{th} storage order identification information when the comparison result indicates that the x^{th} storage order identification information is bigger than (x+1)^{th} storage order identification information;
judging that the storage order of a piece of virtual machine data corresponding to the x^{th} storage order identification information is prior to the storage order of a piece of virtual machine data corresponding to the (x+1)^{th} storage order identification information when the comparison result indicates that the (x+1)^{th} storage order identification information is bigger than x^{th} storage order identification information; and
obtaining the storage order of the virtual machine data belonging to a same virtual machine after performing comparison among the storage order identification information corresponding to the same virtual machine sequentially.

15. The data recovery method according to claim 11, wherein the virtual machine data and the indication information of the virtual machine data from a second electronic device are acquired by a communication module of a first electronic device, and the data recovery method further comprises supplying power to the second electronic device through a communication interface of the first electronic device, the communication interface being an interface through which the communication module is connected to the second electronic device.
